(19) United States
(12) Patent Application Publication
(10) Pub. No.: US 2025/0155069 A1
(43) Pub. Date: May 15, 2025

(54) ANTI-OXIDIZED METAL PIPE AND METHOD OF FABRICATING THE SAME

(71) Applicant: Metal Industries Research & Development Centre, Kaohsiung (TW)

(72) Inventors: Jia-Hao Lin, Hualien County (TW); Chang-Sin Ye, Tainan City (TW); Ping Tun Huang, Changhua County (TW); Zheng-Xi Li, Tainan City (TW)

(73) Assignee: Metal Industries Research & Development Centre, Kaohsiung (TW)

(21) Appl. No.: 18/935,664

(22) Filed: Nov. 4, 2024

(30) Foreign Application Priority Data
Nov. 9, 2023 (TW) 112143152
Oct. 21, 2024 (TW) 113139963

(51) Int. Cl. F16L 58/04; C23C 16/02; C23C 16/04; C23C 16/24; F16L 9/02

(52) U.S. Cl. CPC F16L 58/04; C23C 16/0209; C23C 16/045; C23C 16/24; F16L 9/02

(57) ABSTRACT

Provided are an anti-oxidized metal pipe and a method of fabricating the same. The anti-oxidized metal pipe includes a hollow metal pipe and an anti-oxidized thin film. The hollow metal pipe has an inner diameter in a range of 1.0 mm to 200 mm. An inner surface of the hollow metal pipe is blanketly covered by the anti-oxidized thin film. The anti-oxidized metal pipe has great resistance to oxidation in a highly-oxidizing environment.

### CROSS-REFERENCE TO RELATED APPLICATION

This application claims the priority benefits of Taiwan application Ser. No. 113139963, filed on Oct. 21, 2024, and Taiwan application Ser. No. 112143152, filed on Nov. 9, 2023. The entirety of each of the above-mentioned patent applications is hereby incorporated by reference herein and made a part of this specification.

### BACKGROUND

### Technical Field

The disclosure relates to a pipe and a method of fabricating the same, and particularly relates to an anti-oxidized metal pipe and a method of fabricating the same.

### Description of Related Art

Many metal materials undergo oxidation reactions in oxygen or when exposed to oxidants (that is, in an oxidizing environment), forming an oxide layer on the surface of the metal material. When the metal material is stainless steel, chromium oxide may form on the surface in the oxidizing environment. According to the kinetics curve of metal oxidation, when the stainless steel surface has a thin chromium oxide layer (along with other metal oxide layers) and is placed in an environment with low oxidation concentration, the oxidation curve thereof is logarithmic, indicating only a low probability of further oxidation reactions to occur on the surface. However, if placed in an environment with high oxidation concentration, the oxidation curve thereof may be linear, leading to damage of the chromium oxide and the stainless steel surface is exposed, and the oxidation reaction may occur repeatedly on the stainless steel surface.

Therefore, in order to reduce or prevent the further oxidation reactions of the stainless steel in the environment with high oxidation concentration, an anti-oxidized thin film may be formed on the stainless steel surface to protect the stainless steel from oxidation. The anti-oxidized thin film may use materials more stable than chromium oxide to achieve better protective effects.

In view of the above, there is an urgent need to provide a method of fabricating an anti-oxidized metal pipe so that the interior of the metal pipe is not easily oxidized during use.

### SUMMARY

The disclosure provides an anti-oxidized metal pipe and a method of fabricating the same, and the inner surface thereof is not easily oxidized during use.

The anti-oxidized metal pipe of the disclosure includes a hollow metal pipe and an anti-oxidized thin film. The inner diameter of the hollow metal pipe is in a range of 1.0 mm to 4.5 mm. The anti-oxidized thin film covers at least the inner surface of the hollow metal pipe. The anti-oxidized thin film is tested according to the ASTM G31 standard. The corrosion rate of the anti-oxidized thin film is less than or equal to 2 MPY.

The anti-oxidized metal pipe of the disclosure includes a hollow metal pipe and an anti-oxidized thin film. The inner diameter of the hollow metal pipe is in a range of 1.0 mm to 4.5 mm. The anti-oxidized thin film covers at least the inner surface of the hollow metal pipe. The crystallinity of the anti-oxidized thin film is less than or equal to 40%; the thickness of the anti-oxidized thin film is 50 nm to 1000 nm; the carbon content of the anti-oxidized thin film is less than 300 ppm; the corresponding current density of the anti-oxidized thin film is less than 0.0001 A/cm under a condition that the electric field applied is less than or approximately equal to 50 kV/cm; and/or, the transmittance of the anti-oxidized thin film in the visible light range is less than or approximately equal to 50%.

The method of fabricating the anti-oxidized metal pipe of the disclosure includes the following steps: providing a hollow metal pipe with an inner diameter of 1.0 mm to 200 mm; and, forming the anti-oxidized thin film on at least the inner surface of the hollow metal pipe through a chemical vapor deposition process.

Based on the above, by forming the anti-oxidized thin film on the inner surface of the hollow metal pipe, the inner surface of the hollow metal pipe can be made less likely to be oxidized during use.

### BRIEF DESCRIPTION OF THE DRAWINGS

FIG. 1 is a schematic diagram of an anti-oxidized metal pipe according to an embodiment of the disclosure.

FIG. 2 is a partial cross-sectional view of an anti-oxidized metal pipe according to an embodiment of the disclosure.

FIG. 3 is a partial flow chart of a partial method of fabricating an anti-oxidized metal pipe according to an embodiment of the disclosure.

FIG. 4 is a Raman spectrum chart of [Example 2] and [Comparative Example 2] according to the disclosure.

FIG. 5 is a physical diagram of [Example 3] according to the disclosure.

FIG. 6 is a Raman spectrum chart of [Example 4], [Example 5], [Comparative Example 3], and [Comparative Example 4] according to the disclosure.

FIG. 7 is a graph showing photometric measurement results of [Example 4], [Example 5], [Comparative Example 3] and [Comparative Example 4] according to the disclosure.

FIG. 8 is a graph showing electrical property measurement results of [Example 4], [Example 5], and [Comparative Example 3] according to the disclosure.

### DESCRIPTION OF THE EMBODIMENTS

The following disclosure provides numerous different embodiments or illustrations for implementing various features of the disclosure. Specific examples of components and configurations described below are intended to simplify the disclosure. The embodiments are merely examples and are not intended to be limiting. In addition, the disclosure repeats reference numerals and/or letters across various embodiments, and the repetition is for the sake of simplicity and clarity, and does not imply any relationship between the different embodiments and/or configurations discussed.

As used in the disclosure, “around”, “about”, “approximately”, or “substantially” generally mean within 20%, or within 10%, or within 5% of the stated value or range.

Generally speaking, due to the limitations of the shape and size of the inner wall, the inner wall of the metal pipe is not easy to be modified. In order to enable metal pipes to be used in environments with high oxidation concentrations, following the above, the disclosure provides an anti-oxidized metal pipe and a method of fabricating the same. By depositing an anti-oxidized thin film on the inner surface of a hollow metal pipe and controlling the crystallinity of the anti-oxidized thin film, the anti-oxidized metal pipe maintains great resistance to oxidation in an environment with high oxygen concentration, and/or still has great resistance to acid corrosion in an environment with high acid concentration.

It should be understood that the environment with “high oxygen concentration” mentioned in the disclosure refers to an environment with an oxygen partial pressure concentration of approximately 70% to approximately 95%, or an environment with equivalent oxidizing potential (but excluding fluorine-containing gas, hydrogen fluoride, or similar substances).

It should be understood that the environment with “high acid concentration” mentioned in the disclosure refers to an aqueous solution of hydrochloric acid, nitric acid, or sulfuric acid with a pH value greater than or approximately equal to −0.8 and less than 7, or an environment with equivalent acid concentration (but excluding fluorine-containing acids).

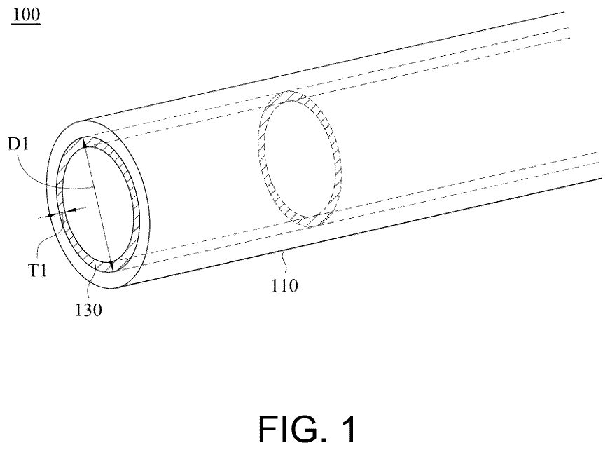

Please refer to FIG. 1, which is a schematic diagram of an anti-oxidized metal pipe 100 according to an embodiment of the disclosure. The anti-oxidized metal pipe 100 includes a hollow metal pipe 110 and an anti-oxidized thin film 130. An inner surface of the hollow metal pipe 110 is blanketly covered by the anti-oxidized thin film 130. In an embodiment, the outer surface of the hollow metal pipe 110 may optionally have the anti-oxidized thin film (not shown in the drawing), that is, the anti-oxidized thin film 130 may blanketly cover the hollow metal pipe 110 completely.

In an embodiment, an inner diameter D1 of the hollow metal pipe 110 is approximately in a range of 1.0 mm to 200 mm, for example, in a range of 3 mm to 200 mm. When the inner diameter D1 of the hollow metal pipe 110 is too small, then it may be detrimental to subsequent use; conversely, when the inner diameter D1 of the hollow metal pipe 110 is too large, then it may be difficult to form a uniform anti-oxidized thin film.

In an embodiment, the hollow metal pipe 110 may include a branch pipe (⅛″ pipe; that is, approximately one-eighth of an inch in diameter of the pipe), a two-part pipe (¼″ pipe; that is, approximately one-quarter of an inch in diameter of the pipe), a quarter pipe (½″ pipe; that is, approximately one-half of an inch in diameter of the pipe), a six-part pipe (¾″ pipe; that is, approximately three-quarters of an inch in diameter of the pipe), a one-inch pipe (1″ pipe; that is, approximately one inch in diameter of the pipe), and a combination of the above (such as connecting with connectors, branch fittings, and adapters).

In an embodiment, the length of the hollow metal pipe may be greater than or approximately equal to 5 cm and less than or approximately equal to 5 meters; for example, the length may be greater than or approximately equal to 10 cm and less than or approximately equal to 3 meters. In an embodiment, the slenderness ratio of the hollow metal pipe 110 is not less than 114.

In an embodiment, before being coated with the anti-oxidized thin film (such as the anti-oxidized thin film 130) as described later, the hollow metal pipe 110 may be bent into an appropriate shape using suitable methods. In an embodiment, the three-dimensional structure of the hollow metal pipe 110 may be an irregular shape or a regular shape. In an embodiment, the hollow metal pipe 110 may be bent into a circular, spiral, or rounded polygon with a radius of curvature of 5 mm to 300 mm. In an embodiment, the hollow metal pipe 110 may have a planar length or width or a diameter of approximately 0.1 cm to 50 cm.

In an embodiment, the material of the hollow metal pipe 110 includes stainless steel, aluminum alloy, copper alloy, or a combination of the above. Although stainless steel pipes are resistant to oxidation and deterioration of the pipe in an environment with low oxidation concentration, if the stainless steel pipes are used in an environment with high oxidation concentration, then the chromium oxide on the surface is damaged, leading to the oxidation and deterioration of the pipe. Therefore, if metal pipes are to be used in environments with high oxidation concentrations, an anti-oxidized thin film has to be formed on the surface to extend the service life.

In an embodiment, the material of the hollow metal pipe 110 may be 304 stainless steel or 316 stainless steel.

In an embodiment, a thickness Tl of the anti-oxidized thin film 130 is approximately in a range of 50 nm to 1000 nm. The anti-oxidized thin film 130 having the thickness range may have better resistance to oxidation and/or better uniformity.

In an embodiment, the crystallinity of the anti-oxidized thin film 130 is less than or approximately equal to 40%; preferably, approximately 1% to approximately 20%. The crystallinity may be measured by X-ray diffraction analysis (XRD) or Raman spectroscopy. If the crystallinity of the anti-oxidized thin film 130 is too large, then the anti-oxidation effect may be poor. When the anti-oxidized metal pipe 100 has the anti-oxidized thin film 130 with the crystallinity range, then the resistance to oxidation may be better.

In an embodiment, the anti-oxidized thin film 130 has an amorphous structure. In an embodiment, the anti-oxidized thin film 130 includes hydrogenated amorphous silicon (a-Si:H). The characteristic peak of the Raman spectrum of hydrogenated amorphous silicon (a-Si:H) lies in a range of 480 cm⁻¹ to 500 cm⁻¹. The characteristic peak of the Raman spectrum of crystalline silicon (c-Si) is approximately 520 cm⁻¹. Therefore, if the characteristic peak of the Raman spectrum of a silicon film (such as the anti-oxidized thin film 130) lies in the range of 480 cm⁻¹ to 500 cm⁻¹, then it is indicated that the film primarily has an amorphous silicon structure.

In an embodiment, the anti-oxidized thin film 130 does not include carbon. Since the anti-oxidized thin film 130 basically does not include carbon (less than 300 ppm; even less than 50 ppm; even less than 10 ppm), the resistance to oxidation may be better. The concentration of elements (such as carbon) may be measured using Energy-dispersive X-ray spectroscopy (EDX).

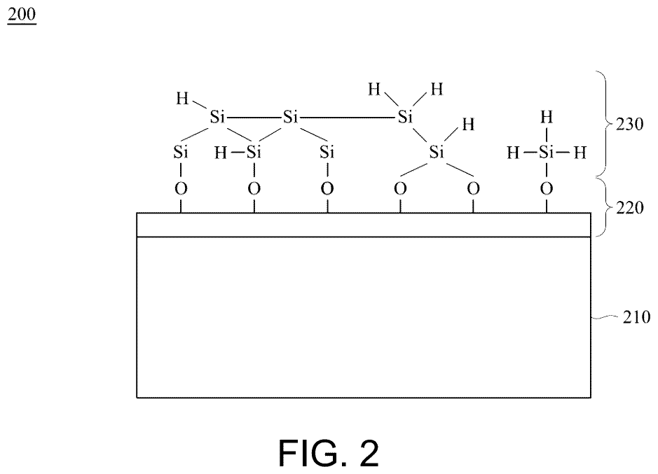

Please refer to FIG. 2, which is a partial cross-sectional view of an anti-oxidized metal pipe 200 according to an embodiment of the disclosure. For example, when the hollow metal pipe 210 includes stainless steel, a layer or part of the metal oxide layer 220 may be formed on the surface of the hollow metal pipe 210 due to oxygen or oxygen atoms, in which the metal oxide layer 220 may include chromium oxide, iron oxide, nickel oxide, or molybdenum oxide.

In an embodiment, the anti-oxidized thin film 230 includes hydrogenated amorphous silicon but does not include carbon. As shown in FIG. 2, the silicon in the anti-oxidized thin film 230 covalently bonds with the oxygen in the metal oxide layer 220 or with elements (such as oxygen or metal elements) in the hollow metal pipe 210, so the anti-oxidized thin film 230 can effectively bond with the metal oxide layer 220 or the hollow metal pipe 210. It may be understood that when the hollow metal pipe 210 includes aluminum alloy or copper alloy, the anti-oxidized thin film 230 formed by the fabrication method of the disclosure also employs a similar bonding mechanism (Si—O bond, Si-metal bond) to be formed on the surface of the pipe.

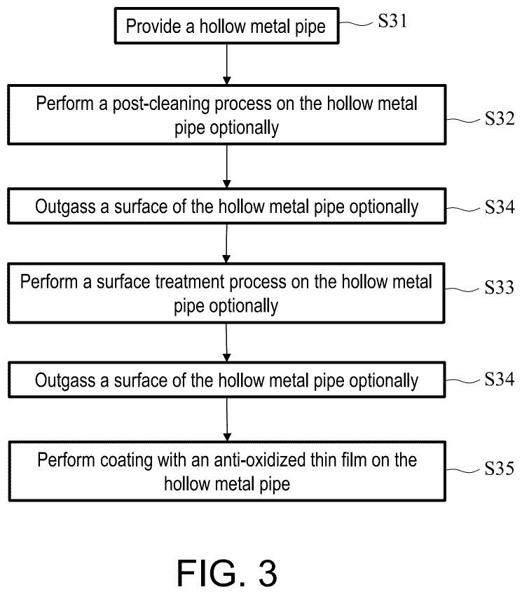

The method of fabricating the anti-oxidized metal pipe 100 will be described below using FIG. 1 and FIG. 3.

Referring to FIG. 3, a hollow metal pipe (for example, the same or similar to the hollow metal pipe 110 in FIG. 1) is provided (that is, Step S31).

In an embodiment, before coating the anti-oxidized thin film 130, a post-cleaning process may be performed on the hollow metal pipe 110 (that is, Step S32) to remove surface impurities, oil stains, and/or slight rust marks. Taking steel as an example, impurities, oil stains, and/or slight rust marks on the surface may be removed by pickling. For example, pickling may be performed by using a hydrochloric acid aqueous solution with a concentration of approximately 10 wt % to 45 wt % at a temperature of approximately 25° C. to 45° C. For example, pickling may be performed by using a sulfuric acid aqueous solution with a concentration of approximately 10 wt % to 25 wt % at a temperature of approximately 50° C. to 80° C. For example, pickling may be performed by using a phosphoric acid aqueous solution with a concentration of approximately 10 wt % to 40 wt % at a temperature of approximately 60° C. to 90° C. In an embodiment, after pickling is completed, the corresponding acid ions may be removed by using water (such as deionized water (DI water)); and then methods such as purging with dry gas, baking, and/or to stand are used for drying.

In an embodiment, a suitable reagent may be introduced into the hollow metal pipe 110 to clean the inner surface of the hollow metal pipe 110.

In an embodiment, before coating the anti-oxidized thin film 130, a surface treatment process may be performed on the hollow metal pipe 110 (that is, Step S33). The surface treatment process may be, for example, allowing hydrogen gas to flow into the hollow metal pipe 110 to perform surface treatment on the inner surface thereof. The inflowing hydrogen flow rate is approximately in a range of 10 sccm to 100 sccm, the temperature is approximately in a range of 200° C. to 700° C., the pressure is approximately in a range of 0.1 Torr to 10 Torr, and the processing time is approximately in a range of 0.1 minutes to 10 minutes; preferably, the hydrogen flow rate is approximately in a range of 10 sccm to 50 sccm, the temperature is approximately in a range of 200° C. to 500° C., the pressure is approximately in a range of 0.1 Torr to 5 Torr, and the processing time is approximately in a range of 0.1 minutes to 3 minutes.

Surface treatment with hydrogen gas can create a reduction-like phenomenon on the treated surface of the hollow metal pipe 110, and/or can reduce the concentration of oxygen atoms and/or nitrogen atoms on the treated surface, which allows the subsequent anti-oxidized thin film 130 to have better contact and blanket coverage with the treated surface of the hollow metal pipe 110. However, when using hydrogen for surface treatment, the temperature should be avoided to be too high (for example: the temperature is greater than 700° C.) and the pressure should be avoided to be too high (for example: the pressure is greater than 10 Torr), and/or the time should be avoided to be too long (the processing time is greater than 10 minutes) to reduce the possibility of hydrogen embrittlement. It is also worth noting that the surface treatment process does not completely eliminate the possibility of oxygen atoms and/or nitrogen atoms on the treated surface. An appropriate amount of oxygen atoms and/or nitrogen atoms may still facilitate the possibility of bonding with the silicon in the subsequent anti-oxidized thin film 230.

In an embodiment, appropriate gas may be introduced into the hollow metal pipe 110 to perform surface treatment on the inner surface of the hollow metal pipe 110.

Referring to FIG. 3, the surface of the hollow metal pipe (for example, the same or similar to the hollow metal pipe 110 in FIG. 1) is outgassed (that is, Step S34). In an embodiment, the hollow metal pipe 110 may be placed in a chamber with a low pressure (for example, less than 1 atmosphere; or less than or approximately 0.5 atmosphere; or less than or approximately 0.1 atmosphere). In this way, the adhesion of molecules (such as gas molecules or water molecules) on the surface of the hollow metal pipe 110 may be reduced through the outgassing phenomenon, which allows the subsequent anti-oxidized thin film 130 to have better contact and blanket coverage with the treated surface of the hollow metal pipe 110. In an embodiment, when the hollow metal pipe 110 is placed in the chamber with the low pressure, the hollow metal pipe 110 may be appropriately heated (for example, greater than 100° C.) to improve the outgassing efficiency.

In an embodiment, outgassing the surface of the hollow metal pipe may be performed after the post-cleaning process (if performed) of the hollow metal pipe 110 and/or before the surface treatment (if performed) with hydrogen of the hollow metal pipe 110. In this way, the subsequent anti-oxidized thin film 130 can have better contact and blanket coverage with the treated surface of the hollow metal pipe 110. In an embodiment, after surface treatment of the hollow metal pipe 110 with hydrogen (if performed), outgassing the surface of the hollow metal pipe may also be performed.

In an embodiment, after the surface treatment of the hollow metal pipe 110 with hydrogen (if performed), the hollow metal pipe 110 may be placed in a chamber with near vacuum (such as: less than or approximately equal to 0.1 Torr; or, less than or approximately equal to 0.05 Torr; or, less than or approximately equal to 0.01 Torr). In this way, the coating of hydrogen molecules on the surface of the hollow metal pipe 110 can be reduced through the outgassing phenomenon, which allows the subsequent anti-oxidized thin film 130 to have better contact and blanket coverage with the treated surface of the hollow metal pipe 110, and/or can reduce the possibility of hydrogen embrittlement. In an embodiment, when placing the hollow metal pipe 110 in the chamber with the low pressure, the hollow metal pipe 110 may be appropriately heated (such as: greater than or approximately equal to 200° C.; or, 200° C. to 700° C.; or, 200° C. to 500° C.) to improve the outgassing efficiency and can still reduce the possibility of hydrogen embrittlement.

In an embodiment, after the post-cleaning process (if performed) of the hollow metal pipe 110 and/or the surface treatment (if performed) with hydrogen gas of the hollow metal pipe 110, a low-pressure chemical vapor deposition process is performed to form the anti-oxidized thin film 130 on the inner surface of the hollow metal pipe 110. In an embodiment, before performing the low-pressure chemical vapor deposition process, the process chamber has to be evacuated first so that the pressure in the process chamber is less than 1.0×10−2 Torr (for example, 6.0×10−3 Torr).

In an embodiment, air may be extracted directly from at least an end of the hollow metal pipe 110 (other ends may be temporarily closed in an appropriate manner) to allow outgassing from the inner surface of the hollow metal pipe 110.

Referring to FIG. 1 and FIG. 3, coating (that is, Step S35) with the anti-oxidized thin film (for example, the same or similar to the anti-oxidized thin film 130 in FIG. 1) is performed on the hollow metal pipe (for example, the same or similar to the hollow metal pipe 110 in FIG. 1).

In an embodiment in which the anti-oxidized thin film 130 is hydrogenated amorphous silicon, during the low-pressure chemical vapor deposition, the process chamber is first heated to the reaction temperature. Then, a mixed gas of silane (SiₙH₂ₙ₊₂) (such as monosilane (SiH₄) or disilane (Si₂H₆)) and hydrogen is introduced into the process chamber for chemical vapor deposition. In an embodiment, based on the volume of hydrogen in the mixed gas being 100 vol %, the volume of silane (SiₙH₂ₙ₊₂) (such as monosilane (SiH₄)) is approximately in a range of 40 vol % to 60 vol %. The anti-oxidized thin film 130 fabricated using the mixed gas ratio can exhibit fewer defects. If the relative concentration of hydrogen is too high, then the coated hollow metal pipe 110 may suffer a phenomenon similar to hydrogen embrittlement; and/or the coating rate may be reduced. If the relative concentration of hydrogen is too low, then the crystallinity may increase.

In an embodiment, the reaction temperature is approximately in a range of 420° C. to 600° C., preferably approximately in a range of 500° C. to 600° C. Utilizing the reaction temperature allows for a more complete reaction, so as to produce an anti-oxidized thin film with low crystallinity and reduce the possibility of producing a film with high crystallinity.

In an embodiment, after the mixed gas is introduced, stable pressure control may be performed for several minutes (for example, approximately in a range of 2 minutes to 3 minutes). In an embodiment, the pressure of the low-pressure chemical vapor deposition process is controlled approximately in a range of 0.1 Torr to 100 Torr. High-quality anti-oxidized thin films of amorphous silicon can be fabricated by chemical vapor deposition using the aforementioned pressure. The thickness of the anti-oxidized thin film may be controlled according to the process time of the low-pressure chemical vapor deposition process. In an embodiment, the low-pressure chemical vapor deposition process may be, for example, to perform chemical vapor deposition for 1 hour to 12 hours.

In an embodiment, after performing the low-pressure chemical vapor deposition process to form a corresponding thin film on the surface of the hollow metal pipe 110, hydrogen gas with an appropriate flow rate/concentration may be purged within an appropriate time range, which may be possible to reduce the number or concentration of silicon dangling bonds to improve the quality of the film.

In an embodiment, an anti-oxidized thin film that is the same as or similar to the anti-oxidized thin film 130 may be formed on the surface of the hollow metal pipe 110 (the inner wall surface of the hollow metal pipe 110) in the aforementioned manner. For example, the mixed gas may be directly introduced into the tube of the hollow metal pipe 110 to form an anti-oxidized thin film the same as or similar to the anti-oxidized thin film 130 on the inner wall surface. In an embodiment, the anti-oxidized thin film 130 only covers the inner wall surface of the hollow metal pipe 110. In an embodiment, the anti-oxidized thin film 130 does not cover the outer surface (that is, another surface relative to the inner wall surface) of the hollow metal pipe 110 completely.

In an embodiment, the thickness of the anti-oxidized thin film may approximately be in a range of 50 nm to 1000 nm. In an embodiment, the uniformity of the anti-oxidized thin film may approximately be in a range of 80% to 100%; preferably, approximately in a range of 85% to 100%. The thickness of the anti-oxidized thin film may be measured by commonly used methods (such as measuring with an electron microscope after sectioning).

In an embodiment, the anti-oxidized thin film (or a similar substance used for stimulation) formed on the surface of the hollow metal pipe 110 is tested using the ASTM G31 (Standard Practice for Laboratory Immersion Corrosion Testing of Metals). The corrosion rate of the anti-oxidized thin film is less than or approximately equal to 2 mm per year (MPY), preferably, less than or approximately equal to 1 MPY.

In an embodiment, the anti-oxidized thin film (or a similar substance used for stimulation) formed on the surface of the hollow metal pipe 110 is measured using a commonly used method (such as X-ray diffraction analysis or Raman spectroscopy), and the crystallinity of the anti-oxidized thin film is not greater than 40%.

In an embodiment, the anti-oxidized thin film (or a similar substance used for stimulation) formed on the surface of the hollow metal pipe 110 is measured using a commonly used method (such as a four-point probe), under a condition that the electric field applied is less than or approximately equal to 50 (kV/cm), the corresponding current density of the anti-oxidized thin film is less than 0.0001 (1×10⁻⁴) A/cm. For example, under a condition that the electric field applied is less than or approximately equal to 50 kV/cm and greater than or approximately equal to 40 kV/cm, the corresponding current density of the anti-oxidized thin film is less than 0.0001 A/cm (1×10⁻⁴ A/cm).

In an embodiment, the anti-oxidized thin film (or a similar substance used for stimulation) formed on the surface of the hollow metal pipe 110 is measured using a commonly used method (such as optical interference method, optical density method (OD), or spectral reflectometry). The transmittance of the anti-oxidized thin film (with a thickness approximately in a range of 50 nm to 1000 nm) in the visible light range (that is, approximately in a range of 400 nm to 780 nm) is less than or approximately equal to 50%.

In view of the fact that the conventional method is not conducive to surface modification inside the pipe, especially pipes with smaller inner diameters, larger slenderness ratios, and/or irregular shapes. In the above description, the pipe with the irregular shape may be, for example, a pipe with multiple bends, and the bending angles may be at least partially the same or different from each other. Therefore, the disclosure utilizes the low-pressure chemical vapor deposition method and controls specific reaction parameter conditions, and the anti-oxidized thin film 130 with high uniformity can be deposited on and blanketly cover the inner surface of the hollow metal pipe 110, and the desired film thickness to be deposited can be effectively controlled. Furthermore, when the anti-oxidized thin film 130 has a specific low crystallinity or is in an amorphous state, a better anti-oxidation effect is achieved, and thus the pipe can be effectively protected and the service life of the pipe can be extended.

### EXAMPLE and COMPARATIVE EXAMPLE

The following uses several [Examples] or [Comparative Examples] to illustrate the application of the disclosure. However, the examples are not intended to limit the disclosure. Persons with ordinary knowledge in the technical field of the disclosure may, without departing from the spirit and scope of the disclosure, make various changes and modifications.

In addition, comparisons between [Examples] and [Comparative Examples]; and/or comparisons between different [Examples] may be based on changes in manipulated variables to explore the impact thereof on the results. Also, between [Examples] and [Comparative Examples] for the comparisons; and/or, between the different [Examples] for the comparisons, the control variables are the same and may be included in the content disclosed in a foregoing embodiment, so the detailed content may be omitted.

### Example 1 and Comparative Example 1

The anti-oxidized metal pipes of [Example 1] formed by 316 stainless steel hollow pipe and an anti-oxidized thin film including hydrogenated amorphous silicon, and the anti-oxidized thin film is formed using the low-pressure chemical vapor deposition method of the disclosure. [Comparative Example 1] is a 316 stainless steel hollow pipe without any modification treatment. The pipes of [Example 1] and [Comparative Example 1] are tested separately. The pipes are sealed in test containers, the temperature is controlled to 20° C., and the test container is filled with a high-concentration oxidizing agent (that is, the oxygen partial pressure concentration is approximately in a range of 70% to 95%).

Since the oxidation-reduction reaction continues to occur in the test container, gas is produced, causing the pressure to rise continuously. Therefore, the change in pressure over time may be used to calculate the terminal pressure increase rate, and the increase rate value is used to convert and calculate the daily decomposition rate and the equivalent decomposition rate. It should be noted that the daily decomposition rate is defined as the ratio of the concentration change to the test time (for example, day), while the equivalent decomposition rate is calculated based on the daily decomposition rate plus the surface area of the pipe and the oxygen concentration of the test environment. The experimental calculation results of the above two are shown in [Table 1]. It should be noted that during the test of [Comparative Example 1], the pressure rose too quickly, and in order to avoid danger, the test was terminated early and only conducted for one day.

TABLE 1

| | Environmental | | Terminal pressure | Daily | Equivalent |
|---|---|---|---|---|---|
| | temperature | Testing time | increase rate | decomposition | decomposition |
| | (° C.) | (day) | (kPa/day) | rate (%/day) | rate (%/day) |
| Example 1 | 20 | 3 | 151.64 | 0.0134 | 0.00189 |
| Comparative | 20 | 1 | 1782.7 | 1.57 | 0.0222 |
| Example 1 | | | | | |

As shown in [Table 1], the daily decomposition rate and the equivalent decomposition rate of [Example 1] are much lower than [Comparative Example 1]. In other words, the anti-oxidized thin film on the pipe of [Example 1] can indeed effectively slow down the oxidation rate of the pipe.

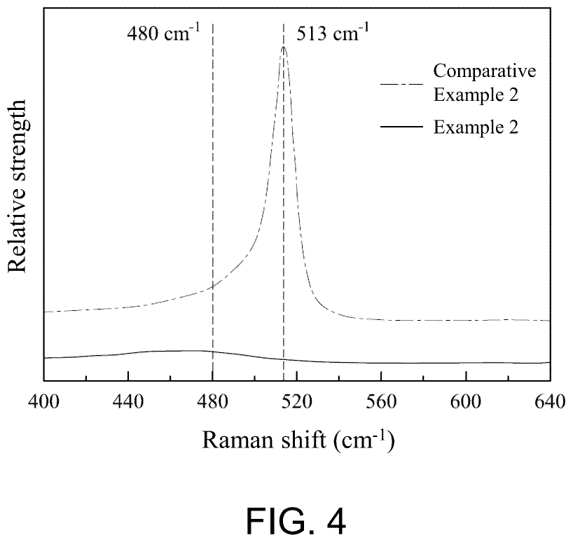

### Example 2 and Comparative Example 2

[Example 2] and [Comparative Example 2] are similar to [Example 1], that is, the inner surface of the stainless steel pipe has the anti-oxidized thin film, in which the anti-oxidized thin film of [Example 2] has an amorphous silicon structure, while the anti-oxidized thin film of [Comparative Example 2] has a silicon structure including polycrystalline and microcrystalline. First, the pipes of [Example 2] and [Comparative Example 2] are tested by Raman Spectroscopy respectively, and the resulting Raman spectra are shown in FIG. 4. As may be seen from FIG. 4, the characteristic peak of [Example 2] is approximately 480 cm⁻¹, while the characteristic peak of [Comparative Example 2] is approximately 513 cm⁻¹. It may be seen from the result that the anti-oxidized thin film of [Example 2] is basically an amorphous silicon structure, while the anti-oxidized thin film of [Comparative Example 2] is basically a silicon structure including polycrystalline and microcrystalline, and the crystallinity is approximately 75.192%.

Next, the pipes of [Example 2] and [Comparative Example 2] are respectively placed into containers filled with high-concentration oxidizing agents (that is, the oxygen partial pressure concentration is approximately in a range of 70% to 95%), the environmental temperature is controlled to 20° C., and the reaction occurs over a period of 30 days. After the reaction is completed, the oxygen concentration in the container is measured to calculate the reaction rate and the oxidation reaction rate of Example 2 and Comparative Example 2 respectively. It should be noted that the reaction rate (for example, decomposition rate) is defined as the ratio of the concentration change to the test time, while the oxidation reaction rate is calculated based on the reaction rate plus the contact area of the pipe and the oxygen concentration of the test environment. The experimental calculation results of the above two are shown in Table 2.

TABLE 2

| | Environmental | | | Oxidation |
|---|---|---|---|---|
| | temperature | Testing time | Reaction rate | reaction rate |
| | (° C.) | (day) | (%/day) | (%/day) |
| Example 2 | 20 | 30 | 0.0036 | 0.00046 |
| Comparative | 20 | 30 | 0.2867 | 0.36385 |
| Example 2 | | | | |

According to [Table 2], the reaction rate and the oxidation reaction rate of Example 2 are lower than Comparative Example 2, and the oxidation reaction rate is approximately 790 times different. In other words, compared to Comparative Example 2 including polycrystalline and microcrystalline silicon, the anti-oxidized thin film including amorphous silicon of Example 2 significantly has better resistance to oxidation.

### <Adhesion Test>

The pipe of [Example 1] is subjected to the “Coatings and Varnishes-Cross Cut Test” of ISO2409 and the “Standard Test Method for Rating Adhesion by Tape Test” of ASTM D3359.

First, grid-shaped cuts are made on the anti-oxidized thin film on the pipe of [Example 1], and then the tape is applied to the cuts. Next, the tape is removed and the degree of removal or damage to the anti-oxidized thin film is assessed based on defined scoring criteria. After experimental observation, the anti-oxidized thin film did not fall off, which means that the hundred-grid adhesion level thereof is the highest level 5B.

In addition, the pipe of [Example 1] is subjected to scratch adhesion analysis using the Revetest® scratch tester, and the measured adhesion is 6.5 N to 11.9 N.

### <Environmental Durability Test>

The anti-oxidized metal pipe of the [Example 2] is subjected to a neutral salt spray test to evaluate the resistance of the metal pipe and the anti-oxidized thin film to salt spray corrosion.

The test simulates a corrosive environment by exposing the pipe to neutral salt water mist. The test solution is an aqueous solution of sodium chloride at a concentration of approximately 5 wt % (40 g/L to 60 g/L) with a pH value of 6.5 to 7.2. The test environment is with the spray volume being 1 ml to 2 ml (80 cm²/hr), the test room temperature is 35±1° C., the pressure barrel temperature is 47±1° C., and the compressed air pressure is 1.00±0.01 kgf/cm². After 1500 hours of neutral salt spray test, the appearance of the anti-oxidized metal pipe of [Example 2] has no significant change from the initial appearance, which means that the anti-oxidized metal pipe with the anti-oxidized thin film have good environmental durability.

### Example 3

In [Example 3], the inner surface of the hollow metal pipe is coated with the anti-oxidized thin film in the manner of the previous embodiment. In [Example 3], the hollow metal pipe used may be a commercially available 316 steel quarter pipe. In addition, multiple hollow metal pipes may be connected with corresponding connectors and taps before being coated with the anti-oxidized thin film, and may be bent according to needs.

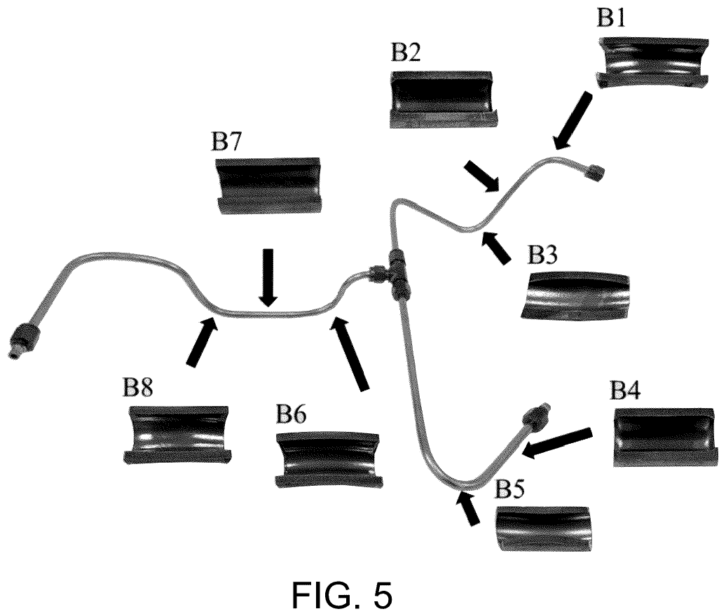

FIG. 5 is a physical diagram of [Example 3] according to the disclosure. For the color version of FIG. 5, please refer to the priority document of Taiwan application (TW113139963) claimed by this disclosure.

As shown in FIG. 5, the anti-oxidized thin film may be evenly coated on the inner wall surface of the hollow metal pipe to form a corresponding anti-oxidized metal pipe. Also, as shown in FIG. 5, different parts of the anti-oxidized metal pipes (such as B1, B2, B3, B4, B5, B6, B7, and B8 shown in FIG. 5) are cut, the thickness of the anti-oxidized thin film on the inner wall surface is measured using commonly used methods. The thickness uniformity of the anti-oxidized thin film is approximately 86.88%.

### Example 4, Example 5, Comparative Example 3, and Comparative Example 4

[Example 4], [Example 5], [Comparative Example 3], and [Comparative Example 4] are steps of coating the anti-oxidized thin film on the inner wall surface of the hollow metal pipe in the same or similar manner. The coating steps include, sequentially: a post-cleaning process is performed on the hollow metal pipe; outgassing the surface of hollow metal pipe; a surface treatment is performed on the hollow metal pipe; outgassing the surface of the hollow metal pipe; performing coating with the anti-oxidized thin film on the hollow metal pipe. Moreover, the hydrogen flow rate of the surface treatment is approximately in a range of 10 sccm to 50 sccm, the temperature is approximately in a range of 200° C. to 500° C., the pressure is approximately in a range of 0.1 Torr to 5 Torr, and the time is approximately in a range of 0.1 minute to 3 minutes.

In addition, the gas used in the coating step of the anti-oxidized thin film is a mixed gas of silane (such as monosilane (SiH₄)) and hydrogen with a concentration ratio of approximately 40% to 60%. The difference is only in the coating step of the anti-oxidized thin film: In [Comparative Example 4], the temperature is approximately 20° C., in [Comparative Example 3], the temperature is approximately 700° C., in [Example 4], the temperature is approximately 500° C., and in [Example 5], the temperature is approximately 600° C.

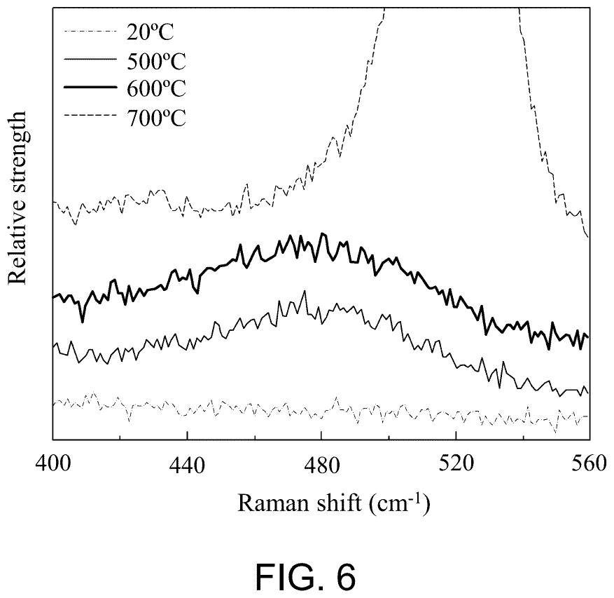

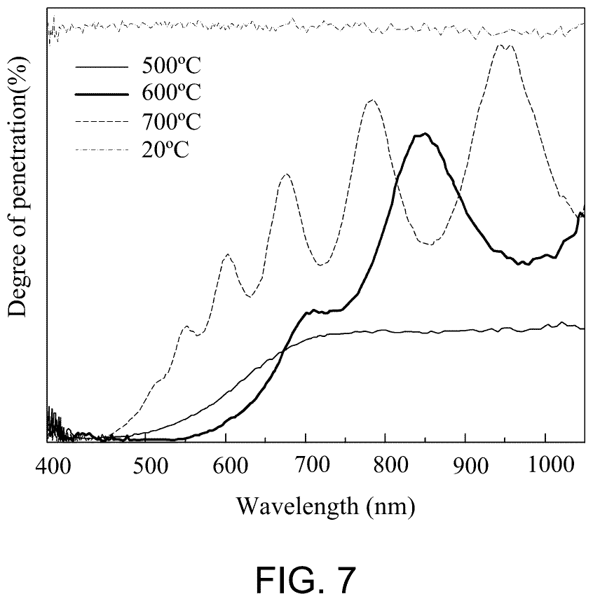

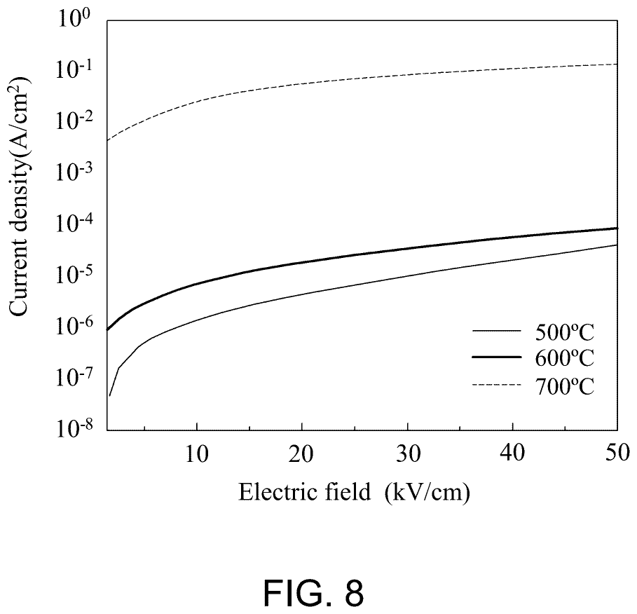

FIG. 6 is a Raman spectrum chart of [Example 4], [Example 5], [Comparative Example 3], and [Comparative Example 4] according to the disclosure. FIG. 7 is a graph showing photometric measurement results of [Example 4], [Example 5], [Comparative Example 3], and [Comparative Example 4] according to the disclosure. FIG. 8 is a graph showing electrical property measurement results of [Example 4], [Example 5], and [Comparative Example 3] of the disclosure. In FIG. 6, FIG. 7, and FIG. 8, the corresponding data of [Example 4] is represented by a thin solid line, the corresponding data of [Example 5] is represented by a thick solid line, the corresponding data of [Comparative Example 3] is represented by a long dotted line, and the corresponding data of [Comparative Example 4] is shown as a dotted line. It is worth mentioning that through inspection by commonly used methods (such as electron microscopy), [Comparative Example 4] does not actually have a complete or significant film layer being coated (that is, there may be no film layer formed on the part to be coated at all, and some other parts only have broken film layers or particles formed on the part to be coated, and cannot be regarded as a complete film layer). Therefore, the electrical measurement shown in FIG. 8 is essentially a measurement on the metal surface of the pipe, and the electrical conductivity is almost similar to the conductor and has no significance for comparison, so it is not listed.

In addition, the coated surface of the pipe is tested according to the ASTM G31 standard, and the corrosion rates are as follows: [Example 4] is approximately 0.823 MPY, [Example 5] is approximately 0.411 MPY, [Comparative Example 3] is approximately 2.057 MPY, and [Comparative Example 4] is approximately 4.113 MPY.

According to the embodiments, the disclosure provides the anti-oxidized metal pipe and the method of fabricating the same by depositing the anti-oxidized thin film on the inner surface of the hollow metal pipe and controlling the crystallinity of the anti-oxidized thin film. Therefore, the anti-oxidized metal pipe can maintain great resistance to oxidation in environments with high oxidation concentrations, and the anti-oxidized thin film has good adhesion.

Although the disclosure has been disclosed in several embodiments, the embodiments are not intended to limit the disclosure. Persons with ordinary knowledge in the technical field to which the disclosure belongs may make various changes and modifications without departing from the spirit and scope of the disclosure. Therefore, the protection scope of the disclosure shall be determined by the appended claims.

What is claimed is:

1. An anti-oxidized metal pipe, comprising:
a hollow metal pipe, wherein the hollow metal pipe has an inner diameter in a range of 1.0 mm to 200 mm; and
an anti-oxidized thin film covering at least an inner surface of the hollow metal pipe, wherein the anti-oxidized thin film is tested according to ASTM G31 standard, and a corrosion rate of the anti-oxidized thin film is less than or equal to 2 MPY.

2. The anti-oxidized metal pipe according to claim 1, wherein a material of the anti-oxidized thin film comprises an amorphous structure.

3. The anti-oxidized metal pipe according to claim 1, wherein the anti-oxidized thin film does not cover an outer surface of the hollow metal pipe.

4. The anti-oxidized metal pipe according to claim 1, wherein a crystallinity of the anti-oxidized thin film is less than or equal to 40%.

5. The anti-oxidized metal pipe according to claim 1, wherein a thickness of the anti-oxidized thin film is in a range of 50 nm to 1000 nm.

6. The anti-oxidized metal pipe according to claim 1, wherein a carbon content of the anti-oxidized thin film is less than 300 ppm.

7. The anti-oxidized metal pipe according to claim 1, wherein a corresponding current density of the anti-oxidized thin film is less than 0.0001 A/cm under a condition that an electric field applied is less than or approximately equal to 50 kV/cm.

8. The anti-oxidized metal pipe according to claim 1, wherein a transmittance of the anti-oxidized thin film in a visible light range is less than or approximately equal to 50%.

9. An anti-oxidized metal pipe, comprising:
a hollow metal pipe, wherein the hollow metal pipe has an inner diameter in a range of 1.0 mm to 200 mm; and
an anti-oxidized thin film covering at least an inner surface of the hollow metal pipe, wherein:
a crystallinity of the anti-oxidized thin film is less than or equal to 40%;
a thickness of the anti-oxidized thin film is in a range of 50 nm to 1000 nm;
a carbon content of the anti-oxidized thin film is less than 300 ppm;
the anti-oxidized thin film has a corresponding current density of less than 0.0001 A/cm under a condition that an electric field applied is less than or approximately equal to 50 kV/cm; and/or
a transmittance of the anti-oxidized thin film in a visible light range is less than or approximately equal to 50%.

10. The anti-oxidized metal pipe according to claim 9, wherein a material of the anti-oxidized thin film comprises an amorphous structure.

11. The anti-oxidized metal pipe according to claim 9, wherein the anti-oxidized thin film does not cover an outer surface of the hollow metal pipe.

12. A method of fabricating an anti-oxidized metal pipe, comprising:
providing a hollow metal pipe with an inner diameter in a range of 1.0 mm to 200 mm; and
forming the anti-oxidized thin film on at least an inner surface of the hollow metal pipe through a chemical vapor deposition process.

13. The method of fabricating the anti-oxidized metal pipe according to claim 12, further comprising:
surface outgassing the inner surface of the hollow metal pipe at least once before forming the anti-oxidized thin film.

14. The method of fabricating the anti-oxidized metal pipe according to claim 12, further comprising:
performing surface treatment on the inner surface of the hollow metal pipe before forming the anti-oxidized thin film, wherein:
the surface treatment comprises allowing hydrogen gas with a flow rate of 10 sccm to 100 sccm to flow through at least the hollow metal pipe;
a temperature of the surface treatment is in a range of 200° C. to 700° C.;
a gas pressure of the surface treatment is in a range of 0.1 Torr to 10 Torr; and/or
an execution time of the surface treatment is in a range of 0.1 minutes to 10 minutes.

15. The method of fabricating the anti-oxidized metal pipe according to claim 14, further comprising:
surface outgassing the inner surface of the hollow metal pipe at least once before forming the anti-oxidized thin film.

16. The method of fabricating the anti-oxidized metal pipe according to claim 15, wherein surface outgassing is performed at least once before and after the surface treatment.

17. The method of fabricating the anti-oxidized metal pipe according to claim 15, wherein:
a temperature of surface outgassing is greater than or equal to 100° C.; and/or
surface outgassing at least places the inner surface of the hollow metal pipe in an atmosphere with an air pressure of less than or equal to 0.1 Torr.

18. The method of fabricating the anti-oxidized metal pipe according to claim 14, wherein the chemical vapor deposition process involves introducing gas through an end of the hollow metal pipe.
